(19) United States
(12) Patent Application Publication
(10) Pub. No.: US 2026/0305034 A1
(43) Pub. Date: Oct. 1, 2026

(54) DISPLAY PANEL AND DISPLAY DEVICE

(71) Applicant: Tianma Advanced Display Technology Institute (Xiamen) Co.,Ltd., Xiamen (CN)

(72) Inventors: Yuqi HU, Xiamen (CN); Mengmeng XIE, Xiamen (CN)

(21) Appl. No.: 19/253,712

(22) Filed: Jun. 27, 2025

(30) Foreign Application Priority Data
Mar. 26, 2025 (CN) 202510363832.8

(51) Int. Cl. H10H 29/49

(52) U.S. Cl. CPC H10H 29/49

(57) ABSTRACT

A display panel and a display device are provided. The display panel includes a first area and a wiring area. The gate driving circuit and the pixel driving circuit of the display panel are located in the first area. The wiring area includes a first type of connection line and a second type of connection line, the first type of connection line is electrically connected to the data line of the display panel, and the second type of connection line is electrically connected to the first signal line of the display panel. The first type of connection line and the second type of connection line at least partially overlap to form an overlap area; and in the overlap area, at least an organic layer is spaced between the first type of connection line and the second type of connection line.

### CROSS-REFERENCE TO RELATED APPLICATION

This application claims the priority of Chinese Patent Application No. 202510363832.8, filed on Mar. 26, 2025, the content of which is incorporated by reference in its entirety.

### TECHNICAL FIELD

The present disclosure generally relates to the field of display technologies and, more particularly, relates to a display panel and a display device.

### BACKGROUND

With the continuous development of science and technology, more and more display products, such as mobile phones, tablet computers, laptops and smart wearable devices, are widely used in people's daily life and work, bringing great convenience to people's daily life and work, and becoming indispensable tools for people today.

To realize the display function of display products, display products are usually arranged with signal lines for transmitting different signals. When signal coupling occurs between signal lines transmitting different signals, stripes of a specific period may appear in the display screen, affecting the display effect. Therefore, how to improve the above problems has become one of the technical problems that need to be solved urgently at this stage. The present disclosed display panels and display devices are direct to solve such a problem and other problems in the arts.

### SUMMARY

One aspect of the present disclosure provides a display panel. The display panel includes a gate driving circuit, a pixel driving circuit, a data line, and a first signal line. The data line is configured to provide a data signal to the pixel driving circuit, and the gate driving circuit is configured to transmit a control signal to the pixel driving circuit. The first signal line is electrically connected to the gate driving circuit and is configured to transmit a control signal to the gate driving circuit. The display panel includes a first area and a wiring area, the gate driving circuit and the pixel driving circuit are located in the first area, and the wiring area is located at a side of the first area adjacent to an edge of the display panel. The wiring area includes a first type of connection line and a second type of connection line, the first type of connection line is electrically connected to the data line, and the second type of connection line is electrically connected to the first signal line. Along a direction perpendicular to a plane where a light-exiting surface of the display panel is located, the first type of connection line and the second type of connection line at least partially overlap to form an overlap area; and in the overlap area, at least an organic layer is spaced between the first type of connection line and the second type of connection line.

Another aspect of the present disclosure provides a display device. The display device includes a display panel. The display panel includes a gate driving circuit, a pixel driving circuit, a data line, and a first signal line. The data line is configured to provide a data signal to the pixel driving circuit, and the gate driving circuit is configured to transmit a control signal to the pixel driving circuit. The first signal line is electrically connected to the gate driving circuit and is configured to transmit a control signal to the gate driving circuit. The display panel includes a first area and a wiring area, the gate driving circuit and the pixel driving circuit are located in the first area, and the wiring area is located at a side of the first area adjacent to an edge of the display panel. The wiring area includes a first type of connection line and a second type of connection line, the first type of connection line is electrically connected to the data line, and the second type of connection line is electrically connected to the first signal line. Along a direction perpendicular to a plane where a light-exiting surface of the display panel is located, the first type of connection line and the second type of connection line at least partially overlap to form an overlap area; and in the overlap area, at least an organic layer is spaced between the first type of connection line and the second type of connection line.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates a top view of an exemplary display panel according to various embodiments of the present disclosure;

FIG. 2 illustrates a layer structure of an exemplary display panel according to various embodiments of the present disclosure;

FIG. 3 illustrates an exemplary gate driving circuit according to various embodiments of the present disclosure;

FIG. 4 illustrates an exemplary partially zoomed-in view of the wiring area and a portion of the first area adjacent to the wiring area of the display panel in FIG. 1;

FIG. 5 illustrates an AA-sectional view in FIG. 4;

FIG. 6 illustrates an exemplary layout structure of a first type of connection line and a second type of connection line in the wiring area;

FIG. 7 illustrates a BB′-sectional view in FIG. 6;

FIG. 8 illustrates another exemplary layout structure of a first type of connection line and a second type of connection line in the wiring area;

FIG. 9 illustrates a CC′-sectional view in FIG. 8;

FIG. 10 illustrates another exemplary layout structure of a first type of connection line and a second type of connection line in the wiring area;

FIG. 11 illustrates a DD′-sectional view in FIG. 10;

FIG. 12 illustrates another exemplary layout structure of a first type of connection line and a second type of connection line in the wiring area;

FIG. 13 illustrates an EE′-sectional view in FIG. 12;

FIG. 14 illustrates another exemplary layout structure of a first type of connection lines and a second type of connection lines in the wiring area;

FIG. 15 illustrates another AA-sectional view in FIG. 4;

FIG. 16 illustrates an exemplary relative positional relationship between a shielding member and the first type of connection lines and the second type of connections lines;

FIG. 17 illustrates another AA-sectional view in FIG. 4;

FIG. 18 illustrates a top view of another exemplary display panel according to various embodiments of the present disclosure;

FIG. 19 illustrates another exemplary partially zoomed-in view of the wiring area and a portion of the first area adjacent to the wiring area of the display panel in FIG. 1;

FIG. 20 illustrates an EE′-sectional view in FIG. 19;

FIG. 21 illustrates another EE′-sectional view in FIG. 19;

FIG. 22 illustrates a top view of another exemplary display panel according to various embodiments of the present disclosure;

FIG. 23 illustrates an exemplary partially zoomed-in view of the wiring area and a portion of the first area adjacent to the wiring area of the display panel in FIG. 22;

FIG. 24 illustrates an exemplary connection structure of the second type of connection line, the auxiliary lead and the second connection soldering pad;

FIG. 25 illustrates a top view of another exemplary display panel according to various embodiments of the present disclosure;

FIG. 26 illustrates a top view of another exemplary display panel according to various embodiments of the present disclosure; and

FIG. 27 illustrates an exemplary display device according to various embodiments of the present disclosure.

### DETAILED DESCRIPTION

To more clearly understand the above-mentioned purpose, features and advantages of the present disclosure, the scheme of the present disclosure will be further described below. It should be noted that, in the absence of conflict, the embodiments of the present disclosure and the features in the embodiments can be combined with each other.

In the following description, many specific details are set forth to facilitate a full understanding of the present disclosure, but the present disclosure can also be implemented in other ways different from those described herein. Obviously, the embodiments in the specification are only part of the embodiments of the present disclosure, not all of the embodiments.

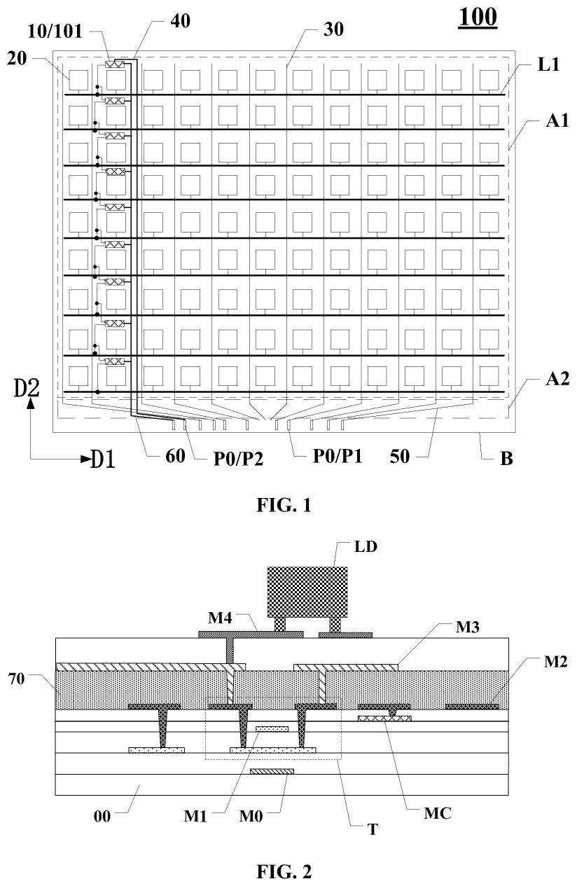

The present disclosure provides a display panel and a display device. FIG. 1 shows a planar structure diagram of an exemplary display panel provided in an embodiment of the present disclosure. FIG. 1 only takes a display panel with a rectangular structure as an example, and does not limit the actual shape of the display panel. In some other embodiments of the present disclosure, the display panel may also be embodied in any other feasible shape such as a circle or a rounded rectangle. The display panel provided in this embodiment may be a display panel using the inorganic light-emitting diode display technology, that is, the light-emitting elements in the display panel may be Micro-LEDs or Mini-LEDs, etc. This type of display panel may have the advantages of high brightness, low power-consumption, and easy splicing, and may be widely used in display products. The connection relationship of the light-emitting element in the display panel may be appropriately referred to FIG. 2, which shows a layer schematic diagram of the display panel provided by the embodiment of the present disclosure. The light-emitting element LD may be electrically connected to the pixel driving circuit 20 in the display panel. It should be noted that FIG. 2 only illustrates a film layer structure of the display panel, and does not limit the actual number and size of the film layers. The detailed film layer structure in FIG. 2 will be described in subsequent embodiments.

In some other embodiments of the present disclosure, the display panel may also be embodied as an organic light-emitting display panel, and the corresponding light-emitting element may be an organic light-emitting element (such as OLED), which is not specifically limited in the present disclosure.

It should be noted that, to clearly illustrate the relative position relationship between the gate driving circuit 10, the pixel driving circuit 20, the data line 30 and the first signal line 40, other structures of the display panel such as the light-emitting element LD are not shown in FIG. 1, and the pixel driving circuit 20 is only illustrated in a rectangular structure, and the number and arrangement of the pixel driving circuit 20 may not be limited. In addition, the position of the gate driving circuit 10 in the display area in FIG. 1 is only for illustration. In some other embodiments of the present disclosure, the gate driving circuit 10 may also be set at other positions in the display area, which will be described in subsequent embodiments. It should also be noted that FIG. 1 only takes the display panel including one group of gate driving circuits 10 as an example, but is not limited to this. In some other embodiments of the present disclosure, the display panel may also include two or more groups of gate driving circuits 10.

FIG. 3 is a schematic diagram of a structure of a gate driving circuit 10 provided in an embodiment of the present disclosure. As shown in FIG. 3, the gate driving circuit 10 may include a plurality of cascaded shift registers 11. The input terminal IN of the shift register 11 at the first stage may be connected to the start trigger signal line STV, and may be used to receive the start trigger signal transmitted by the start trigger signal line STV, and the input terminal IN of the shift registers at other stages may be connected to the output terminal OUT of the shift register 11 at the previous stage. The shift registers 11 at each stage may be respectively connected to the first clock signal line CK and the second clock signal line XCK, and may be used to receive the clock signal. The shift registers at each stage may also be respectively connected to the first level signal line vgh and the second level signal line vgl, and may be used to receive the first level signal and the second level signal. In one embodiment, the first level signal may be a high-level signal, and the second level signal is a low-level signal. The output terminals of the shift registers at each stage may be respectively connected to the scan line L1, and may be used to transmit the control signal to the pixel drive circuit 20 through the scan line L1. It should be noted that the connection relationship of the gate driving circuit 10 in the embodiment of FIG. 3 is only for illustration, and the present disclosure is not limited thereto. The embodiment of FIG. 1 is only described by taking the shift register located between two adjacent rows of pixel driving circuits 20 as an example, but the present disclosure is not limited thereto. In some other embodiments of the present disclosure, the shift register may also be located between two adjacent columns of pixel driving circuits 20.

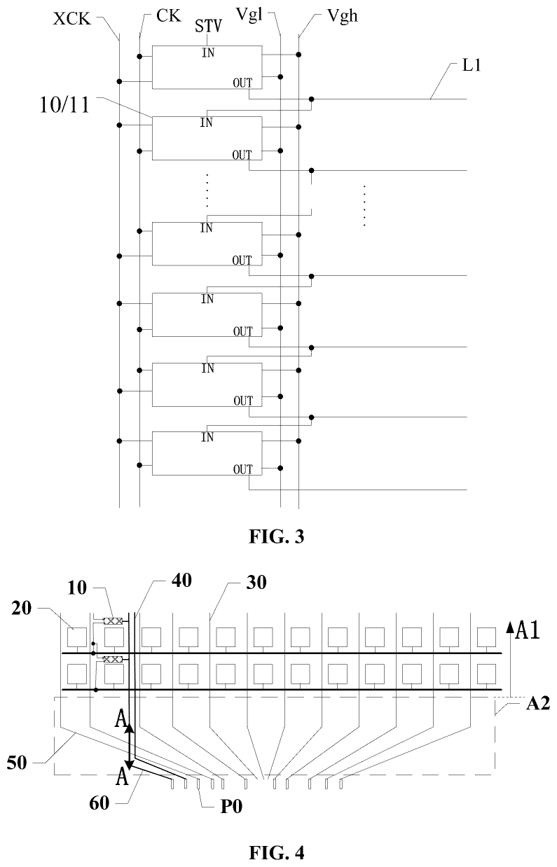

FIG. 4 shows a partial enlarged schematic diagram of the wiring area A2 of the display panel in FIG. 1 and a portion of the first area A1 adjacent to the wiring area A2. As shown in FIG. 1 and FIG. 4, a display panel 100 provided in one embodiment of the present disclosure may include a gate driving circuit 10, a pixel driving circuit 20, a data line 30 and a first signal line 40. The data line 30 may be configured to provide a data signal to the pixel driving circuit 20, and the gate driving circuit 10 may be configured to transmit a control signal to the pixel driving circuit 20. The control signal transmitted to the pixel driving circuit 20 may include, for example, a reset control signal, a data writing control signal, and a light-emitting control signal, etc. The first signal line 40 may be electrically connected to the gate driving circuit 10, and may be used to transmit a control signal to the gate driving circuit 10. The first signal line 40 may include, for example, at least one of the first clock signal line CK, the second clock signal line XCK, and the start trigger signal line STV shown in FIG. 3. The control signal transmitted by the first signal line 40 to the gate driving circuit 10 may include, for example, a clock signal, or a start trigger signal, etc.

The display panel 100 may include a first area A1 and a wiring area A2. The gate driving circuit 10 and the pixel driving circuit 20 may be located in the first area A1. The wiring area A2 may be located on the side of the first area A1 adjacent to the edge B of the display panel. Taking FIG. 1 as an example, the wiring area A2 may be equivalent to the area set between the first area A1 and the lower edge B of the display panel. The wiring area A2 may include a first type of connection line 50 and a second type of connection line 60. The first type of connection line 50 may be electrically connected to the data line 30, and the second type of connection line 60 may be electrically connected to the first signal line 40. In one embodiment, a connection pad P0 may be provided in the wiring area A2 toward the lower edge of the display panel, and the first type of connection line 50 and the second type of connection line 60 may be both electrically connected to the connection pad P0, thereby realizing the electrical connection between the data line 30 and the first signal line 40 and the connection pad P0. In some other embodiments of the present disclosure, the connection pad P0 may be electrically connected to the control chip IC located on the back of the display panel through the upper side wiring of the display panel to realize the extremely narrow frame or frameless design of the display panel, but the present disclosure is not limited to this. The connection pad P0 may also be directly bonded to the control chip or the flexible circuit board, and the present disclosure does not specifically limit this.

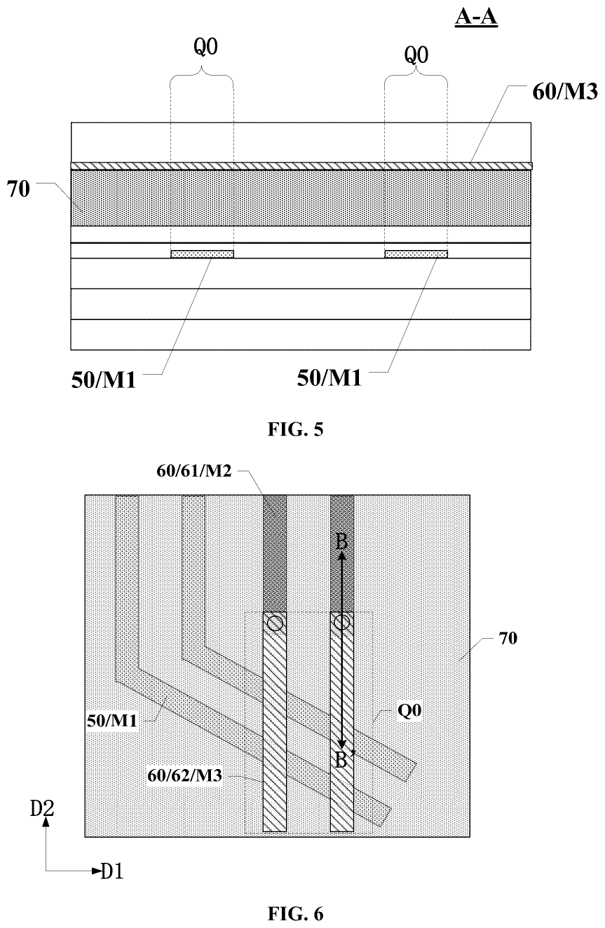

FIG. 5 shows an AA-sectional view in FIG. 4. As shown in FIG. 4 and FIG. 5, in the direction perpendicular to the plane where the light-exiting surface of the display panel is located, the first type of connection line 50 and the second type of connection line 60 may at least partially overlap to form an overlap area Q0. In the overlap area Q0, at least an organic layer 70 may be spaced between the first type of connection line 50 and the second type of connection line 60.

The display area of the display panel in the embodiment of the present disclosure may include the aforementioned first area A1, and the light-emitting elements may be uniformly arranged in the first area A1. In some other embodiments of the present disclosure, the display area may also include the first area A1 and the wiring area A2 at the same time, and the light-emitting elements may be uniformly arranged in the first area A1 and the wiring area A2.

Further, referring to FIG. 1, FIG. 4 and FIG. 5, in one embodiment of the present disclosure, when the gate driving circuit 10 is introduced into the display panel, the gate driving circuit 10 and the pixel driving circuit 20 may be both arranged in the first area A1. The first area A1 may belong to the display area. The gate driving circuit 10 may not occupy the space of the non-display area. In this way, the non-display area may be set in the display panel, or only a non-display area with a smaller width may be set, which may be conducive to realizing a frameless or extremely narrow frame design of the display panel.

In another embodiment, when the gate driving circuit 10 is set in the first area A1, the first signal line 40 connected to the gate driving circuit 10 may be connected to the connection pad P0 through the second type of connection line 60 in the wiring area A2, and the data line 30 connected to the pixel driving circuit 20 may be connected to the connection pad P0 through the first type of connection line 50 in the wiring area A2. The first signal line 40 may be interspersed between different data lines 30, and the first type of connection line 50 and the second type of connection line 60 may overlap in the orthographic projection of the wiring area A2 and form an overlap area Q0. Because the first type of connection line 50 may be used to transmit data signals and the second type of connection line 60 may be used to transmit clock signals or start trigger signals, the signals transmitted on the first type of connection line 50 and the second type of connection line 60 may be both jumping signals. If signal coupling occurs between the two, it may affect the normal display of the display panel. To this end, in the embodiment of the present disclosure, in the overlap area of the first type of connection line 50 and the second type of connection line 60, at least an organic layer 70 may be spaced between the first type of connection line 50 and the second type of connection line 60. The organic layer 70 may be, for example, a film layer that may play a flattening role in the display panel and may have a relatively large thickness. When the first type of connection line 50 and the second type of connection line 60 are separated by the organic layer 70 at least in the overlap area, it may be equivalent to increasing the distance between the first type of connection line 50 and the second type of connection line 60 in the overlap area. When the first type of connection line 50 and the second type of connection line 60 in the overlap area are used as two plates of a capacitor, the greater the distance between the two plates, the smaller the coupling capacitance between the two plates will be, which may be conducive to reducing the coupling capacitance generated when the first type of connection line 50 and the second type of connection line 60 overlap, and may be conducive to weakening or eliminating the phenomenon of abnormal display stripes caused by the coupling capacitance, so it may be conducive to improving the overall display effect.

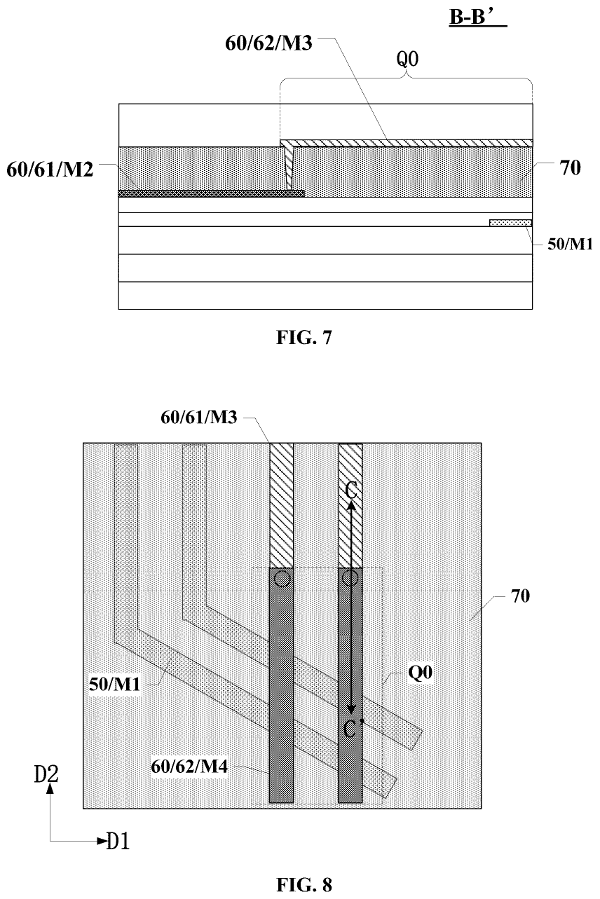

FIG. 6 shows a wiring schematic diagram of the first type of connection line 50 and the second type of connection line 60 in the wiring area A2, and FIG. 7 shows a BB′-sectional view of FIG. 6. As shown in FIG. 4, FIG. 6 and FIG. 7, in one embodiment of the present disclosure, the second type of connection line 60 may include a main body 61 and a connection member 62 connected to the main body 61, and the connection member 62 may be located in the overlap area Q0. Along the direction perpendicular to the light-emitting surface of the display panel, the connection member 62 may be located on the side of the organic layer 70 facing the light-emitting surface, and the first type of connection line 50 may be located on the side of the organic layer 70 away from the light-exiting surface.

In this embodiment, the connection member 62 in the second type of connection line 60 may be located in the overlap area Q0, that is, the connection member 62 may overlap with the first type of connection line 50. At this time, the connection member 62 and the first type of connection line 50 may be respectively arranged on both sides of the organic layer 70 along the thickness direction thereof, and the connection member 62 may be closer to the light-exiting surface of the display panel, and the first type of connection line 50 may be closer to the backlight surface of the display panel. Because the first type of connection line 50 and the second type connection line 60 may ultimately need to be electrically connected to different connection pads P0, the film layer where the connection pads P0 are located may usually be closer to the backlight surface of the display panel, that is, it may be arranged on the side of the organic layer 70 away from the light-exiting surface of the display panel. Considering that there may be a large number of data lines 30 in the display panel, the number of first type of connection lines 50 connected to the data lines 30 may also be relatively large. If a relatively large number of first type of connection lines 50 are arranged on the side of the organic layer 70 facing the light-exiting surface of the display panel, the difficulty of the manufacturing process may increase when connecting this part of the first type of connection lines 50 to the connection pads P0 under the organic layer 70. Considering that the number of first signal lines 40 in the display panel may be small, the number of second type of connection lines 60 connected to the first signal lines 40 may also be small. Even when the connection member 62 arranged on the side of the organic layer 70 facing the light-exiting surface of the display panel is introduced into the second type of connection line 60, the process of electrically connecting the small number of connection members 62 to the connection pads P0 may be relatively simple. Therefore, in this embodiment, the connection member 62 of the second type of connection line 60 may be arranged on the side of the organic layer 70 facing the light-exiting surface, and the first-type connection line 50 may be arranged on the side of the organic layer 70 away from the light-exiting surface, which may be conducive to reducing the coupling capacitance between the first type of connection line 50 and the second type of connection line 60, and simplifying the manufacturing process of the display panel. It should be noted that the embodiment of the present disclosure is only described by arranging the first type of connection line 50 corresponding to the data line 30 on the side of the organic layer 70 away from the light-emitting surface of the display panel, and the connection member 62 in the second type of connection line 60 on the side of the organic layer 70 facing the light-exiting surface of the display panel, but the present disclosure is not limited to this. In some other embodiments of the present disclosure, the first type of connection line 50 corresponding to the data line 30 may also be arranged on the side of the organic layer 70 facing the light-exiting surface of the display panel, and the connection member 62 in the second type of connection line 60 may be arranged on the side of the organic layer 70 away from the light-emitting surface of the display panel, which may also reduce the coupling capacitance between the first type of connection line 50 and the second type of connection line 60 and may improve the overall display effect.

Further, referring to FIG. 4, FIG. 6 and FIG. 7, in one embodiment of the present disclosure, the main body 61 of the second type of connection line 60 may be located on the side of the organic layer 70 away from the light-exiting surface. In this embodiment, the main body 61 in the second type of connection line 60 may be regarded as the part directly connected to the first signal line 40. The main body 61 may not overlap with the first type of connection line 50. The connection member 62 may be located on the side of the main body 61 facing the edge of the display panel. The connection member 62 may overlap with the first type of connection line 50. Therefore, the connection member 62 may be equivalent to a jumper to the side of the organic layer 70 facing the light-exiting surface relative to the main body 61 to reduce the coupling capacitance between the first type of connection line 50 and the second type of connection line 60. Considering that the first signal line 40 connected to the main body 61 may be located on the side of the organic layer 70 away from the light-exiting surface of the display panel, that is, located below the organic layer 70, the main body 61 directly connected to the first signal line 40 may be set on the side of the organic layer 70 away from the light-exiting surface, which may be conducive to reducing the difficulty of connecting the main body 61 with the first signal line 40.

Further, referring to FIG. 4 and FIG. 6, in one embodiment of the present disclosure, the main body 61 in the second type of connection line 60 may be set on the same layer as the first signal line 40. In this way, the main body 61 and the first signal line 40 may be made in the same process and connected. Compared with the solution that requires two manufacturing processes and requires the introduction of vias for connection when the main body and the first signal line are set in different film layers, the solution of setting the main body 61 and the first signal line 40 connected thereto in the same layer in this embodiment may be conducive to simplifying the manufacturing process and improving production efficiency.

The above embodiments show a scheme in which the main body 61 and the connection member 62 of the second type of connection line 60 are respectively arranged on the side of the organic layer 70 away from the light-exiting surface and the side facing the light-exiting surface. In some other embodiments of the present disclosure, the main body 61 and the connection member 62 of the second type of connection line 60 may also be arranged on the side of the organic layer 70 facing the light-exiting surface of the display panel.

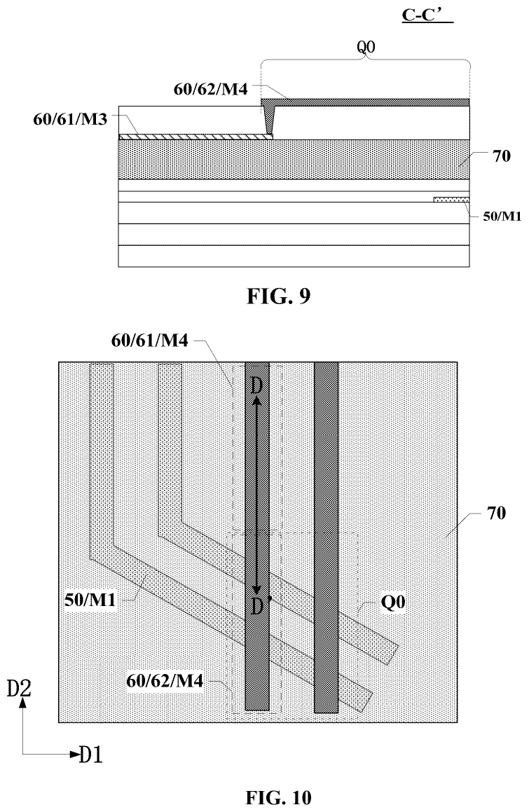

FIG. 8 shows another exemplary wiring schematic diagram of the first type of connection line 50 and the second type of connection line 60 in the wiring area A2. FIG. 9 shows a CC′-sectional view of FIG. 8. As shown in FIGS. 8-9, in one embodiment of the present disclosure, the main body 61 of the second type of connection line 60 may be located on the side of the organic layer 70 facing the light-exiting surface.

When the main body 61 and the connecting member 62 of the second type of connection line 60 are both arranged above the organic layer 70, that is, on the side of the organic layer 70 facing the light-exiting surface of the display panel, the main body 61 and the connection member 62 may be no longer separated by a thicker organic layer 70, which may be conducive to simplifying the difficulty of connecting the main body 61 and the connection member 62. In one embodiment, the first signal line 40 may also be disposed on the side of the organic layer 70 facing the light-exiting surface of the display panel, for example, it may be disposed on the same layer as the main body 61, thereby simplifying the overall manufacturing process of the first signal line 40 and the main body 61, and simplifying the connection between the two.

Further, referring to FIGS. 8 and 9, when the main body 61 and the connection member 62 in the second type of connection line 60 are both arranged on the side of the organic layer 70 facing the light-exiting surface of the display panel, in one embodiment of the present disclosure, the connection member 62 may be located on the side of the main body 61 facing the light-exiting surface. That is to say, compared with the main body 61, the distance between the connection member 62 and the organic layer 70 may be greater. Considering that the connection member 62 may overlap with the first type of connection line 50, and the first type of connection line 50 may be located on the side of the organic layer 70 away from the light-exiting surface of the display panel, therefore, in one embodiment, when the connection member 62 in the second type of connection line 60 is arranged on the side of the main body 61 away from the organic layer 70, it may be beneficial to increase the longitudinal distance between the connection member 62 and the first type of connection line 50, thereby further reducing the signal coupling between the first type of connection line 50 and the second type of connection line 60, and further weakening or eliminating the display stripes caused by signal coupling.

When the main body 61 and the connection member 62 in the second type of connection line 60 are both arranged on the side of the organic layer 70 facing the light-exiting surface of the display panel, the above embodiment shows a scheme of arranging the main body 61 and the connection member 62 in different film layers. In some other embodiments of the present disclosure, the main body 61 and the connection member 62 in the second type of connection line 60 may also be arranged in the same film layer.

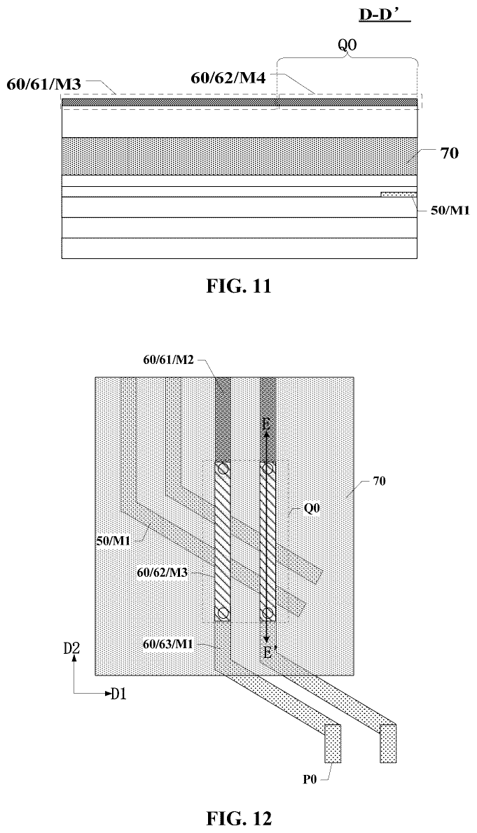

FIG. 10 shows another exemplary wiring schematic diagram of the first type of connection line 50 and the second type of connection line 60 in the wiring area A2, and FIG. 11 shows a DD′-sectional view of FIG. 10. As shown in FIGS. 10-11, in one embodiment of the present disclosure, the main body 61 and the connection member 62 of the second type of connection line 60 may be arranged in the same layer. In this way, the main body 61 and the connection member 62 in the second type of connection line 60 may be manufactured in the same manufacturing process, without the need to use vias to achieve the connection between the two, which may be conducive to simplifying the manufacturing process of the second type of connection line 60.

It should be noted that the specific film structure of the main body and the connection member in the second type of connection line and the first type of connection line in the aforementioned embodiment is only for illustration, and the present disclosure is not limited thereto.

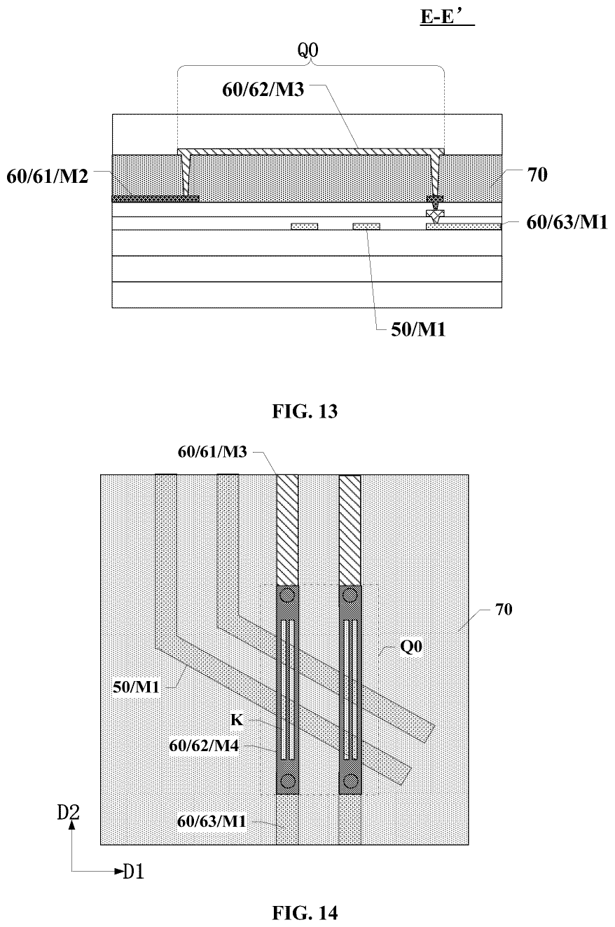

FIG. 12 shows another wiring schematic diagram of the first type of connection line 50 and the second type of connection line 60 in the wiring area A2, and FIG. 13 shows an EE′-sectional view of FIG. 12. As shown in FIG. 1, FIG. 12 and FIG. 13, in one embodiment of the present disclosure, the second type of connection line 60 may include a main body 61 and a lead-out member 63 connected to the main body 61. The lead-out member 63 may be located on the side of the organic layer 70 away from the light-emitting surface, and the lead-out member 63 may be located on the side of the main body 61 adjacent to the edge B of the display panel. It should be noted that the main body 61 and the lead-out member 63 connected to the main body 61 mentioned in the embodiment of the present disclosure may be directly connected or connected through other connection structures. In this embodiment, the main body 61 and the lead-out member 63 are connected through the connection member 62, but it is not limited thereto.

In conjunction with FIG. 1, FIG. 12 and FIG. 13, the lead-out member 63 in the second type of connection line 60 may be regarded as an intermediate component connected to the connection pad P0 in the display panel. The film layer where the connection pad P0 is located may usually be located on the side of the organic layer 70 away from the light-emitting surface of the display panel, that is, located below the organic layer 70, or there may be no organic layer at the location of the connection pad P0. To reduce or avoid the coupling capacitance between the first type of connection line 50 and the second type connection line 60, the present disclosure may at least arrange the portion of the second type of connection line 60 that overlaps with the first type of connection line 50 on the side of the organic layer 70 facing the light-emitting surface of the display panel. At this time, to realize the connection between the second type of connection line 60 and the connection pad P0, it may be necessary to lead the line segment of the second type of connection line 60 arranged on the side of the organic layer 70 facing the light-emitting surface to the side of the organic layer 70 away from the light-emitting surface. Therefore, the second connection line segment in this embodiment may also include a lead-out member 63, which may be located on the side of the organic layer 70 away from the light-exiting surface. One end of the lead-out member 63 may be connected to the line segment of the second connection line segment arranged on the side of the organic layer 70 facing the light-exiting surface through a via hole, and the other end may be connected to the connection pad P0, so that the electrical connection between the second connection line segment and the connection pad P0 may be realized through the lead-out member 63.

FIG. 14 shows another exemplary wiring schematic diagram of the first type of connection line 50 and the second type of connection line 60 in the wiring area A2. As shown in FIG. 5, in one embodiment of the present disclosure, the second type of connection line 60 may include an opening K. In the direction perpendicular to the plane where the light-exiting surface of the display panel is located, the opening K may overlap with the overlap area between the first type of connection line 50 and the second type of signal line 60. When the first type of connection line 50 and the second type of connection line 60 overlap, the present embodiment may form an opening K on the second type of connection line 60, and the opening K may penetrate through the second type of connection line 60 from the thickness direction of the second type of connection line 60. The opening K may be at least located in the overlap area of the first type of connection line 50 and the second type of connection line 60, so that it may be helpful to reduce the actual overlap area of the first type of connection line 50 and the second type of connection line 60 in the overlapping area, and by reducing the actual overlapping area of the two, it may be helpful to further reduce the coupling capacitance between the two, so as to further reduce or eliminate the problem of abnormal display stripes caused by the influence of the coupling capacitance.

It should be noted that FIG. 14 only illustrates a method of setting the opening K on the second type of connection line 60, and does not limit the number, size and shape of the opening K actually set on the second type of connection line 60. Moreover, FIG. 14 only takes the scheme of setting an opening K only on the connection member 62 overlapping with the first type of connection line 50 when the second type of connection line 60 includes a main body 61 and a connection member 62 arranged in different layers as an example for explanation. When the main body 61 and the connection member 62 in the second type of connection line 60 are arranged in the same layer, the opening K may also be set on the connection member 62 overlapping with the first type of connection line 50. Moreover, no matter which film layer the connection member 62 in the second type of connection line 60 is located in, the actual overlapping area of the second type of connection line 60 and the first type of connection line 50 may be reduced by setting the opening K.

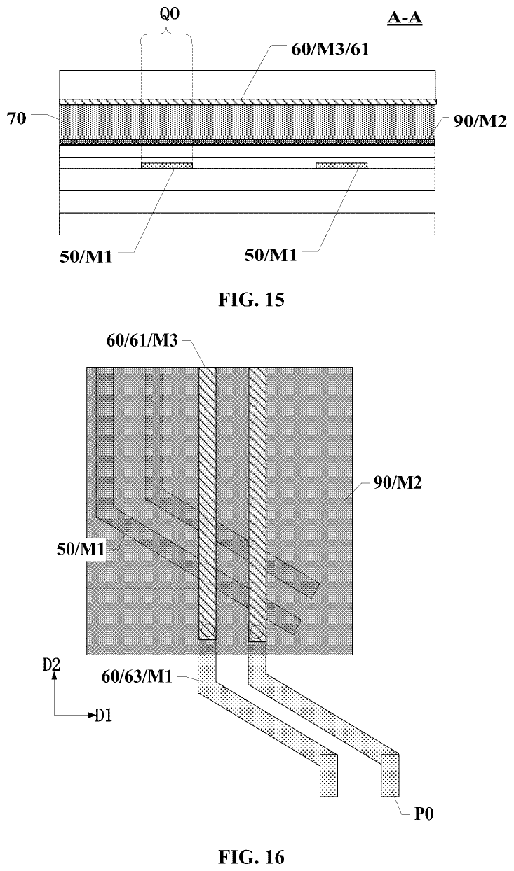

FIG. 15 shows another AA-sectional view of FIG. 4. As shown in FIG. 15, in one embodiment of the present disclosure, the display panel may also include a shielding member 90 at least located in the overlapping area. The shielding member 90 may be located between the first type of connection line 50 and the second type of connection line 60 in a direction perpendicular to the plane where the light-exiting surface of the display panel is located. The shielding member 90 may receive a constant potential signal.

In the present disclosure, in the overlap area Q0, the scheme of arranging the first type of connection line 50 and the second type of connection line 60 on both sides of the organic layer 70 along the thickness direction thereof increases the distance between the first type of connection line 50 and the second type of connection line 60 in the overlap area, which may be conducive to reducing the coupling capacitance formed between the first type of connection line 50 and the second type of connection line 60. On this basis, in one embodiment, a shielding member 90 may be further introduced between the first type of connection line 50 and the second type of connection line 60 in the overlap area Q0, and the shielding member 90 that receives the constant potential signal may shield the signals of the first type of connection line 50 and the second type of connection line 60 to avoid the coupling of the signals of the first type of connection line 50 and the second type of connection line 60 to form a coupling capacitance, thereby facilitating the elimination of the coupling capacitance generated by the overlap of the first type of connection line 50 and the second type of connection line 60, so as to avoid the problem of abnormal display stripes caused by the influence of the coupling capacitance, and thus more conducive to improving the display effect of the display panel.

It should be noted that the constant potential signal received by the shielding member 90 may be a constant potential signal originally existing in the display panel, such as a constant high-level signal or a constant low-level signal, etc., so there may be no need to introduce a new signal for the shielding member 90, which may be conducive to simplifying the design of the display panel.

FIG. 16 shows a relative position relationship diagram of the shielding member 90 and the first type of connection line 50 and the second type of connection line 60. The corresponding film layer diagram may be referred to FIG. 15. As shown in FIG. 15 and FIG. 16, in one embodiment of the present disclosure, the second type of connection line 60 may include a main body 61. Along the direction perpendicular to the plane where the light-emitting surface of the display panel is located, the main body 61 may overlap with the first type of connection line 50, and the shielding member 90 may cover the main body 61.

This embodiment shows a scheme in which the main body 61 in the second type of connection line 60 may overlap with the first type of connection line 50. The main body 61 may be located on the side of the organic layer 70 facing the light-emitting surface of the display panel. To achieve electrical connection between the second type of connection line 60 and the connection pad P0, the second type of connection line 60 may further include a lead-out member 63. The lead-out member 63 may be located on the side of the organic layer 70 facing away from the light-emitting surface of the display panel. The main body 61 in the second connection type of connection line 60 may be electrically connected to the connection pad P0 through the lead-out member 63. In this embodiment, when the shielding member 90 covers the main body 61, the shielding member 90 may be regarded as a planar structure arranged in the wiring area A2, so that the coverage of the shielding member 90 may be larger, and the shielding effect of the signal between the first type of connection line 50 and the second type of connection line 60 may be better.

In conjunction with FIG. 1 and FIG. 2, in one embodiment of the present disclosure, the display panel may include a first metal layer M1, a capacitor metal layer MC, a second metal layer M2 located on the side of the organic layer 70 away from the light-exiting surface, and a third metal layer M3 and a fourth metal layer M4 located on the side of the organic layer 70 toward the light-exiting surface. The capacitor metal layer MC may be located between the first metal layer M1 and the second metal layer M2, and the second metal layer M2 may be located on the side of the capacitor metal layer MC toward the organic layer 70. The fourth metal layer M4 may be located on the side of the third metal layer M3 away from the organic layer 70. The first area A1 of the display panel may include a plurality of transistors T. The gate of the transistor may be located in the first metal layer M1, and the source and drain may be located in the second metal layer M2. In the first area A1 of the display panel, the first metal layer M1 and the second metal layer M2 may also be provided with a plurality of signal lines, and similarly, the third metal layer M3 and the capacitor metal layer MC may both be used for the layout of the signal lines. The capacitor metal layer MC may also be used to overlap with the second metal layer M2 or the first metal layer M1 to form a storage capacitor in the pixel driving circuit 20. In one embodiment, the pad connected to the electrode of the light-emitting element may be located in the fourth metal layer M4.

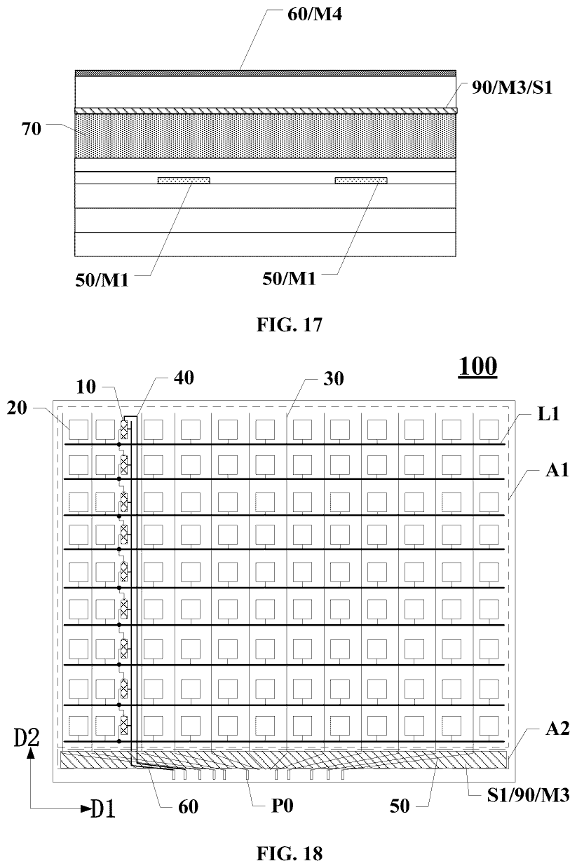

In the wiring area A2, the first type of connection line 50 may be located on the side of the organic layer 70 away from the light-emitting surface of the display panel. Specifically, the first type of connection line 50 may be located in the first metal layer M1 and/or the capacitor metal layer MC. In one embodiment, the display panel may also include an auxiliary metal layer M0 disposed on the side of the first metal layer M1 away from the organic layer 70, and the auxiliary metal layer M0 may overlap with the channel region of the transistor to play a light-shielding role to prevent light from affecting the transistor. When the display panel includes the aforementioned auxiliary metal layer M0, in one embodiment, the first type of connection line 50 may also be located in the auxiliary metal layer M0. When the shielding member 90 is introduced between the first type of connection wire 50 and the second type of connection wire 60, the shielding member 90 may be arranged on the side of the organic layer 70 away from the light-emitting surface of the display panel, or on the side of the organic layer 70 facing the light-emitting surface of the display panel according to actual needs, for example, the shielding member 90 may be located in the second metal layer M2 and/or the third metal layer M3. The embodiment shown in FIG. 15 shows a scheme in which the shielding member 90 is located in the second metal layer M2. When the shielding member 90 is located in the second metal layer M2, the line segment of the corresponding second type of connection line 60 that overlaps with the first type of connection line 50 may be located in the third metal layer M3 or the fourth metal layer M4. When the shielding member 90 is located in the third metal layer M3, for example, referring to FIG. 17 that shows another AA-sectional view of FIG. 4, at this time, the line segment of the second type of connection line 60 that overlaps with the first type of connection line 50 may be located in the fourth metal layer M4. The present disclosure does not specifically limit this. Referring to FIG. 17, the present disclosure sets the shielding member 90 in the existing film layer in the display panel, and there may be no need to introduce a new film layer structure for the shielding member 90 separately, which may be conducive to simplifying the overall structure of the display panel.

Further, referring to FIG. 16, when the main body 61 of the second type of connection line 60 that overlaps with the first-type connection line 50 is located on the side of the organic layer 70 facing the light-emitting surface of the display panel, in one embodiment of the present disclosure, the second type connection line 60 may also include a lead-out member 63 connected to the main body 61. In the same second type of connection line 60, the lead-out member 63 may be located on the side of the main body 61 adjacent to the edge of the display panel, and the lead-out member 63 may be located in the first metal layer M1 and/or the capacitor metal layer MC. When the lead-out member 63 is introduced into the second type connection line 60, the lead-out member 63 may be located on the side of the organic layer 70 away from the light-exiting surface of the display panel, and the electrical connection between the main body 61 in the second type of connection line 60 and the connection pad P0 may be achieved through the lead-out member 63. Considering that the connection pad P0 in the display panel may be arranged on the side of the organic layer 70 away from the light-exiting surface of the display panel, when the lead-out member 63 is introduced into the second type of connection line 60, the lead-out member 63 may be used as an intermediate medium to electrically connect the connection pad P0 with the line segment of the second type of connection line 60 located on the side of the organic layer 70 facing the light-exiting surface of the display panel, and when the lead-out member 63 is arranged on the first metal layer M1 and/or the capacitor metal layer MC, it may be helpful to simplify the connection difficulty of the lead-out member 63 and the connection pad P0.

The embodiment shown in FIG. 16 is described by taking the lead-out member 63 and the connection pad P0 both located in the first metal layer M1 as an example, but the present disclosure is not limited to this. In some other embodiments of the present disclosure, the lead-out member 63 and the connection pad P0 may also be both located in the capacitor metal layer MC, or the lead-out member 63 corresponding to at least one second connection line may be located in the first metal layer M1, and the lead-out member 63 corresponding to at least one second connection line may be located in the capacitor metal layer MC, and the connection pad P0 may be located in the first metal layer M1 or the capacitor metal layer MC.

FIG. 18 shows another planar structure diagram of an exemplary display panel provided by one embodiment of the present disclosure. As shown in FIG. 18, the wiring area A2 may also include a power signal line S1, and the power signal line S1 may be multiplexed as a shielding member 90. The power signal line S1 may be, for example, a positive power voltage signal line that provides a positive power signal to the pixel driving circuit 20, or a negative power voltage signal line that provides a negative power signal to the pixel driving circuit 20. The signal transmitted on the power signal line S1 may be a constant power signal. At this time, the power signal line S1 located in the wiring area A2 may be multiplexed as the shielding member 90. Referring to FIG. 17, the line segment of the second type of connection line 60 that overlaps with the first type of connection line 50 may be located on the side of the power signal line S1 facing the light-exiting surface of the display panel, and the first type of connection line 50 may be located on the side of the power signal line S1 away from the light-exiting surface of the display panel. In the direction perpendicular to the light-emitting surface of the display panel, the shielding member 90 may isolate the overlap area of the second type of connection line 60 and the first type of connection line 50, and the power signal line S1 may be a planar structure as a whole, so it may form a better signal shielding effect, avoiding the generation of coupling capacitance between the first type of connection line 50 and the second type of connection line 60 due to the overlap. Accordingly, it may be beneficial to eliminate the influence of the coupling capacitance on the display effect, such as the generation of unnecessary display stripes, so it may be beneficial to improve the overall display effect of the display panel.

In one embodiment, the power signal line S1 of the wiring area A2 may be multiplexed as the shielding member 90 between the first type of connection line 50 and the second type of connection line 60. There may be no need to introduce a new structure as the shielding member 90 in the display panel. The existing power signal line S1 may be multiplexed. Therefore, while reducing or eliminating the influence of the coupling capacitance between the first type of connection line 50 and the second type of connection line 60, it may also be beneficial to simplify the overall structure of the display panel.

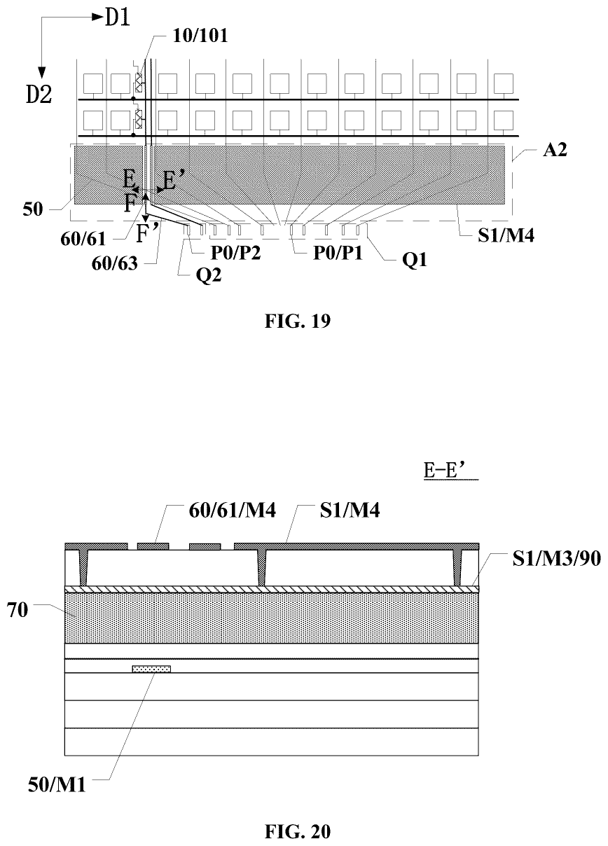

FIG. 19 shows another partial enlarged schematic diagram of the wiring area A2 of the display panel in FIG. 1 and a part of the first area A1 adjacent to the wiring area A2. FIG. 20 shows an EE′-sectional view of FIG. 19. As shown in FIG. 19 and FIG. 20, in one embodiment of the present disclosure, the wiring area A2 may also include a power signal line S1, and the second type of connection line 60 and the power signal line S1 may be at least partially arranged in the same layer and insulated from each other. Taking into account that the power signal line S1 may need to provide a power signal to each pixel driving circuit 20 in the first area A1, to reduce the voltage drop of the power signal and reduce the difference in the power signal that may be received by the pixel driving circuit 20 in different areas, the power signal line S1 in the wiring area A2 may usually be set to a planar structure. In one embodiment, the wiring area A2 may also distribute the power signal line S1 in at least two metal layers. The parallel design of the two metal layers may be conducive to further reducing the impedance on the power signal line S1 and reducing the voltage drop. When the second type of connection line 60 is introduced into the wiring area A2 and at least a portion of the line segments of the second type of connection line 60 are arranged on the side of the organic layer 70 facing the light-exiting surface of the display panel, this embodiment shows a scheme in which the second type of connection line 60 in the wiring area A2 is at least partially arranged in the same layer as the power signal line S1 and insulated. At this time, the second type of connection line 60 may disconnect the power signal line S1 of the original planar structure. However, considering that the power signal line S1 may be distributed on at least two metal layers, the power signal line S1 arranged in the same layer as the second type of connection line 60 may be electrically connected to the power signal line S1 of the planar structure on other metal film layers. Therefore, even if it may be disconnected by the second type of connection line 60, it may not affect the transmission of the power signal on the power signal line S1. In this embodiment, a portion of the line segments of the second type of connection line 60 may be arranged in the same layer as the power signal line S1.

When the organic layer 70 is placed on the side of the light-exiting surface of the display panel, the second type of connection line 60 may be placed on the same layer as the power signal line S1. There may be no need to introduce a separate film layer structure for the second type of connection line 60, which may be conducive to the rational use of the existing film layer of the display panel and may simplify the overall film layer structure of the display panel. The specific film layers of the second type of connection line 60 and the power signal line S1 in the display panel will be described below.

Referring to FIG. 2, FIG. 19 and FIG. 20, in one embodiment of the present disclosure, the display panel may include a first metal layer M1, a capacitor metal layer MC and a second metal layer M2 located on the side of the organic layer 70 away from the light-exiting surface, and a third metal layer M3 and a fourth metal layer M4 located on the side of the organic layer 70 facing the light-exiting surface. The capacitor metal layer MC may be located between the first metal layer M1 and the second metal layer M2, and the second metal layer M2 may be located on the side of the capacitor metal layer MC facing the organic layer 70, and the fourth metal layer M4 may be located on the side of the third metal layer M3 away from the organic layer 70. The second type connection line 60 may include a main body 61, and the main body 61 may overlap with the first type of connection line 50 along the direction perpendicular to the plane where the light-exiting surface of the display panel is located. The power signal line S1 may be distributed at least in the third metal layer M3 and the fourth metal layer M4, and the main body 61 may be located in the third metal layer M3 or the fourth metal layer M4.

This embodiment shows a scheme in which the power signal line S1 is distributed on the third metal layer M3 and the fourth metal layer M4. The power signal lines S1 distributed on the third metal layer M3 and the fourth metal layer M4 may be connected in parallel through vias to reduce the overall impedance of the power signal line S1 and reduce the signal voltage drop on the power signal line S1. In this embodiment, the main body 61 of the second type of connection line 60 that overlaps with the first type of connection line 50 may be arranged on the side of the organic layer 70 facing the light-exiting surface of the display panel, and the main body 61 may be arranged on the fourth metal layer M4 as an example for explanation. In this way, the distance between the main body 61 of the first type of connection line 50 and the second type of connection line 60 in the overlap area may be increased, thereby effectively reducing the coupling capacitance between the first type of connection line 50 and the second type of connection line 60, which may be conducive to reducing or eliminating the influence of the coupling capacitance on the display effect. When the main body 61 of the second type of connection line 60 is arranged in the same layer as the power signal line S1 located in the fourth metal layer M4, the power signal line S1 located in the third metal layer M3 may be multiplexed as the shielding member 90. In the direction perpendicular to the plane where the light-exiting surface of the display panel is located, the shielding member 90 may be located between the main body 61 of the second type of connection line 60 and the first type of connection line 50, which may effectively shield the signal coupling between the first type of signal line and the second type of signal line, and avoid the formation of coupling capacitance between the two and affecting the display effect. It should be noted that, in this embodiment, the main body 61 in the second type of connection line 60 may only be arranged in the same layer as the power signal line S1 located in the fourth metal layer M4, but the present disclosure is not limited to this. In some other embodiments of the present disclosure, the main body 61 in the second type of connection line 60 may also be arranged in the same layer as the power signal line S1 located in the third metal layer M3. In this case, the main body 61 of the second type of connection line 60 may be isolated from the first type of connection line 50 by the organic layer 70, which may also reduce the signal coupling between the first type of connection line 50 and the second type of connection line 60.

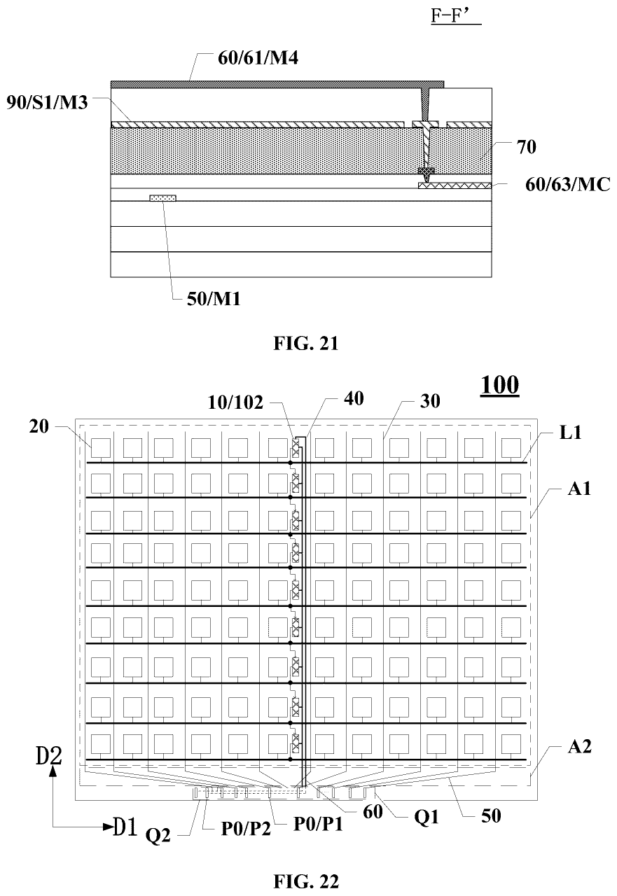

FIG. 21 shows an FF′-sectional view of FIG. 19. As shown in FIG. 19 and FIG. 21, in one embodiment of the present disclosure, the second type of connection line 60 may also include a lead-out member 63 connected to the main body 61. In the same second type of connection line 60, the lead-out member 63 may be located on the side of the main body 61 adjacent to the edge of the display panel, and the lead-out member 63 may be located in the first metal layer M1 or the capacitor metal layer MC.

When the main body 61 of the second type of connection line 60 overlaps with the first type of connection line 50, to reduce the coupling capacitance between the second type of connection line 60 and the first type of connection line 50, the present disclosure may set the main body 61 of the second type of connection line 60 on the side of the light-exiting surface of the organic layer 70 facing the display panel. To achieve the electrical connection between the main body 61 of the second type of connection line 60 and the connection pad P0, the present disclosure introduces a lead-out member 63 set on the side of the organic layer 70 away from the light-exiting surface of the display panel, and the lead-out member 63 may be electrically connected to the main body 61 through a via. Considering that the connection pad P0 may be located on the side of the organic layer 70 away from the light-exiting surface of the display panel, the lead-out member 63 may be set on the first metal layer M1 or the capacitor metal layer MC in this embodiment to facilitate the electrical connection between the lead-out member 63 and the connection pad P0. This embodiment is described by taking the example that the main body 61 of the second type of connection line 60 is located in the fourth metal layer M4 and the lead-out member 63 is located in the capacitor metal layer MC. In this case, the power signal line S1 located in the third metal layer M3 may be multiplexed as the shielding member 90 to shield the signal between the main body 61 and the first type of connection line 50. However, the present disclosure is not limited to this. In some other embodiments of the present disclosure, the main body 61 of the second type of connection line 60 may also be set in the third metal layer M3, and the lead-out member 63 may be set in the first metal layer M1.

In conjunction with FIG. 1 and FIG. 19, in one embodiment of the present disclosure, the wiring area A2 may include a connection soldering pad P0. The connection soldering pad P0 may be located on the side of the first type of connection line 50 and the second type of connection line 60 adjacent to the edge B of the display panel. The connection soldering pad P0 may include a first connection soldering pad P1 and a second connection soldering pad P2. The first connection soldering pad P1 may be electrically connected to the first type of connection line 50, and the second connection soldering pad P2 may be electrically connected to the second type of connection line 60. The wiring area A2 may include a first soldering pad area Q1 and a second soldering pad area Q2 located at least on one side of the first soldering pad area Q1 along a first direction D1. The first connection soldering pad P1 may be located in the first soldering pad area Q1, and the second connection soldering pad P2 may be located in the second soldering pad area Q2, and the first direction D1 may be parallel to the extension direction of the edge B of the display panel.

In one embodiment of the present disclosure, the second type of connection line 60 may be electrically connected to the first signal line 40 for providing a control signal to the gate driving circuit 10, and the first type of connection line 50 may be electrically connected to the data line 30 for providing a data signal to the data line 30. Compared with the data lines 30 in the display panel, the number of the first signal lines 40 may be relatively small, and the number of the corresponding second type of connection lines 60 and second connection soldering pads P2 may be relatively small, while the number of the first type of connection lines 50 corresponding to the first connection soldering pads P1 may be relatively large. In this embodiment, the first connection soldering pads P1 may be uniformly arranged in the first soldering pad area Q1, and the second connection soldering pads P2 with a smaller number may be arranged in the second soldering pad area Q2. The second soldering pad area Q2 may be located on at least one side of the first soldering pad area Q1 along the first direction D1, so that the second connection soldering pads P2 may not affect the original arrangement and connection of the first connection soldering pads P1, which may be more conducive to the matching of the connection soldering pads P0 of the wiring area A2 with the soldering pads on the control chip, without adjusting the structure of the soldering pads on the control chip, which may be conducive to reducing costs.

It should be noted that FIG. 1 and FIG. 19 only show a solution in which a second soldering pad area Q2 is provided on one side of the first soldering pad area Q1 along the first direction D1 when the display panel includes a group of gate driving circuits 10. When the display panel includes two or more groups of gate driving circuits 10, a second soldering pad area Q2 may be provided on both sides of the first soldering pad area Q1 along the first direction D1, respectively. The present disclosure does not specifically limit this.

Further, referring to FIG. 19 and FIG. 21, in one embodiment of the present disclosure, the second type of connection line 60 may include a main body 61 and a lead-out member 63 connected to the main body 61. The main body 61 may be located on the side of the organic layer 70 facing the light-exiting surface, and the lead-out member 63 may be located on the side of the organic layer 70 away from the light-exiting surface. The main body 61 may be electrically connected to the second connection pad P2 through the lead-out member 63.

In the present disclosure, to reduce the coupling capacitance caused by the overlap of the first type of connection line 50 and the second type of connection line 60, the main body 61 of the second type of connection line 60 that overlaps with the first type of connection line 50 may be arranged on the side of the organic layer 70 facing the light-exiting surface of the display panel, and the first type of connection line 50 may be arranged on the side of the organic layer 70 facing away from the light-exiting surface of the display panel, thereby reducing the coupling capacitance by increasing the distance between the two. When the main body 61 of the second type of connection line 60 may be arranged on the side of the organic layer 70 facing the light-exiting surface of the display panel, when the lead-out member 63 may be introduced into the second type of connection line 60, the lead-out member 63 may be located on the side of the organic layer 70 facing away from the light-exiting surface of the display panel, and the electrical connection between the main body 61 of the second type of connection line 60 and the connection soldering pad P0 may be achieved through the lead-out member 63. Considering that the connection soldering pad P0 in the display panel may be arranged on the side of the organic layer 70 away from the light-exiting surface of the display panel, when the lead-out member 63 is introduced into the second type of connection line 60, the lead-out member 63 may be used as an intermediate medium to electrically connect the connection pad P0 with the line segment of the second type of connection line 60 located on the side of the organic layer 70 facing the light-emitting surface of the display panel.

Further, referring to FIG. 1 and FIG. 19, in one embodiment of the present disclosure, the gate driving circuit 10 may include a first group of gate driving circuits 101. Along the second direction D2, the first group of gate driving circuits 101 may not overlap with the first soldering pad area Q1 and the second soldering pad area Q2. The second direction D2 may intersect with the first direction D1.

This embodiment shows that when the first group of gate driving circuits 101 are introduced into the first area A1 of the display panel, the first group of gate driving circuits 101 may be arranged in the first area A1 near the edge of the display panel extending along the second direction D2. Considering that, to facilitate the connection between the wiring in the first area A1 and the connecting soldering pad P0, the first soldering pad area Q1 and the second soldering pad area Q2 may be generally arranged as a whole in the middle position below the first area A1. Therefore, along the second direction D2, the first group of gate driving circuits 101 may not overlap with the first soldering pad area Q1 and the second soldering pad area Q2. In the present disclosure, the second soldering pad area Q2 may be arranged on at least one side of the first soldering pad area Q1 along the first direction D1, so that the first group of gate driving circuits 101 and the second soldering pad area Q2 may be located on the same side of the first soldering pad area Q1 along the first direction D1. In this way, when the second type of connection line 60 corresponding to the first signal line 40 is electrically connected to the second connection soldering pad P2 in the second soldering pad area Q2, the second type of connection line 60 may be connected to the second connection soldering pad P2 nearby to reduce the number of the first type of connection lines 50 overlapping with the second type of connecting lines 60, thereby facilitating the reduction of the coupling capacitance between the second type of connection line 60 and the first type of connection line 50, and thus facilitating the improvement of the display effect of the display panel.

It should be noted that the embodiment of FIG. 19 only shows a solution in which a display panel includes a first group of gate driving circuits 101 and the first group of gate driving circuits 101 is arranged in the first area A1 adjacent to the edge of the display panel extending along the second direction D2. In some other embodiments of the present disclosure, the display panel may also include two first groups of gate driving circuits 101, and the two first groups of gate driving circuits 101 may be arranged respectively adjacent to the two edges of the display panel extending along the second direction D2. Correspondingly, two second soldering pad areas Q2 may be arranged, and the two second soldering pad areas Q2 may be located on both sides of the first soldering pad area Q1 along the first direction D1. The present disclosure does not specifically limit this.

The above embodiment shows a scheme in which the gate driving circuit 10 may be arranged near the edge of the display panel extending along the second direction D2 when the gate driving circuit 10 is introduced into the first area A1. In some other embodiments of the present disclosure, the gate driving circuit 10 may also be arranged near the center of the first area A1 in the first area A1. For example, referring to FIG. 22, which is another planar structure diagram of an exemplary display panel provided by one embodiment of the present disclosure, the gate driving circuit 10 may include a first group of gate driving circuits 102. The first group of gate driving circuits 102 may overlap with the first soldering pad area Q1 along the second direction D2, and the second direction D2 may intersect with the first direction D1. When the first group of gate driving circuits 102 is arranged near the center area of the first area A1, the gate driving circuit 10 may transmit the scanning signal from the middle area of the scanning line L1 to both sides of the scanning line L1, thereby facilitating the transmission efficiency of the scanning signal. It should be noted that the embodiment of FIG. 22 only shows a solution of setting a first group of gate driving circuits 102 near the central area of the first area A1. In some other embodiments of the present disclosure, two or more first groups of gate driving circuits 102 may be set near the central area of the first area A1, and the present disclosure does not specifically limit this. It should also be noted that when the first group of gate driving circuits 102 are set near the central area of the first area A1, the shift register in the first group of gate driving circuits 102 may be arranged as shown in FIG. 22, and located between two adjacent columns of pixel driving circuits 20, but the present disclosure is not limited to this. In some other embodiments of the present disclosure, the shift register may also be located between two adjacent rows of pixel driving circuits 20.

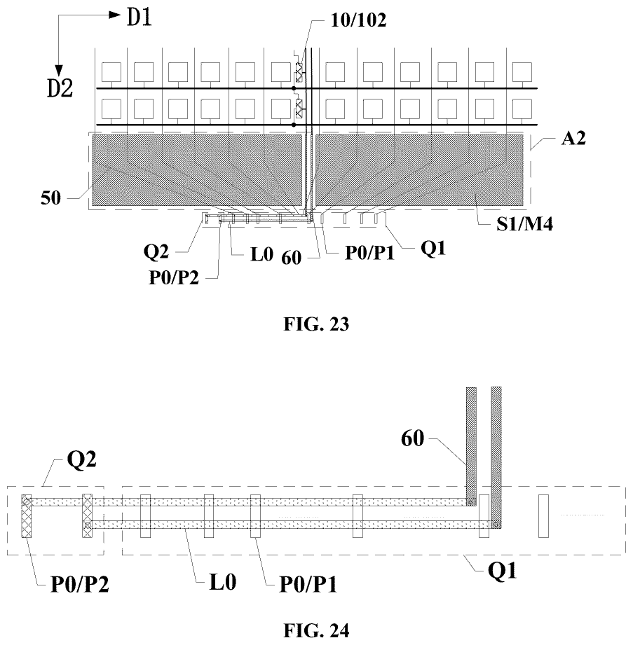

FIG. 23 shows a partially enlarged schematic diagram of the wiring area A2 of the display panel in FIG. 22 and a portion of the first area A1 adjacent to the wiring area A2, and FIG. 24 shows a connection schematic diagram of the second type of connection line, the auxiliary lead and the second connection soldering pad. As shown in FIG. 23 and FIG. 24, in one embodiment of the present disclosure, in the wiring area A2, the second type of connection line 60 may extend along the second direction D2, and the second direction D2 may intersect with the first direction D1. The wiring area A2 may also include an auxiliary lead L0. One end of the auxiliary lead L0 may be electrically connected to the second connection soldering pad P2, and the other end may be electrically connected to the end of the second type of connection line 60 away from the first area A1.

In this embodiment, to avoid changing the control chip structure, the second soldering pad area Q2 where the second connection soldering pad P2 is located may still be arranged on at least one side of the first soldering pad area Q1 along the first direction D1 in the present disclosure. When the first group of gate driving circuits 101 may be arranged at a position adjacent to the center area of the first area A1. Because the second type of connection line 60 connected to the first signal line 40 may be far away from the second connection soldering pad P2, if the electrical connection with the second connection soldering pad P2 may be achieved by pulling an oblique line, the second type of connection line 60 may overlap with more first type of connection line 50, and may form coupling capacitors with different first type of connection lines 50, which may not be conducive to improving the display effect. Therefore, in this embodiment, the second type of connection line 60 may be extended along the second direction D2, which may reduce the number of first type of connection lines 50 overlapped with the second type of connection lines 60, thereby reducing the signal coupling between the second type of connection lines 60 and the first type of connection lines 50, and improving the display effect. When the second type of connection line 60 extends along the second direction D2, the auxiliary lead L0 may be further introduced in this embodiment, and the auxiliary lead L0 may be used to connect the second type of connection line 60 and the corresponding second connection soldering pad P2 respectively, so as to realize the electrical connection between the second type of connection line 60 and the second connection soldering pad P2, and then realize the electrical connection between the first signal line 40 and the second connection soldering pad P2.

Further, referring to FIGS. 23-24, in one embodiment of the present disclosure, the auxiliary lead L0 may not overlap with the first type of connection line 50 in the direction perpendicular to the plane where the light-exiting surface of the display panel is located. When the auxiliary lead L0 is introduced to connect the second type of connection line 60 and the corresponding second connection pad P2, the auxiliary lead L0 may be avoided from overlapping with the first type of connection line 50 in this embodiment, which may be conducive to avoiding the coupling of the signal on the auxiliary lead L0 with the signal on the first type of connection line 50 and affecting the display effect.

Further, referring to FIG. 23 and FIG. 24, in one embodiment of the present disclosure, the auxiliary lead L0 may be located on the side of the connection pad P0 away from the light-emitting surface in a direction perpendicular to the plane where the light-emitting surface of the display panel is located. Referring to FIG. 2, when the auxiliary lead L0 is introduced into the display panel, the auxiliary lead L0 may be set in the film layer below the connection pad P0. When the connection pad P0 is located in the capacitor metal layer MC, the auxiliary lead L0 may be set in the first metal layer M1 or the auxiliary metal layer M0. When the connection soldering pad P0 is located in the first metal layer M1, it may be seen that the auxiliary lead may be set in the auxiliary metal layer M0. In this way, the method of wiring the auxiliary lead on the side of the connection soldering pad P0 away from the light-exiting surface of the display panel may reduce the space occupied by the auxiliary lead and the connection soldering pad P0 on the display panel along the second direction D2, thereby facilitating the realization of a narrow frame or an extremely narrow frame design of the display panel.

It should be noted that, in the embodiment of the present disclosure, when the connection soldering pad P0 is provided in the wiring area A2, the connection pad P0 may be used to bond with the control chip IC or the flexible circuit board FPC, or may be extended to one side of the backlight surface of the display panel through the side routing and then bonded with the control chip IC.

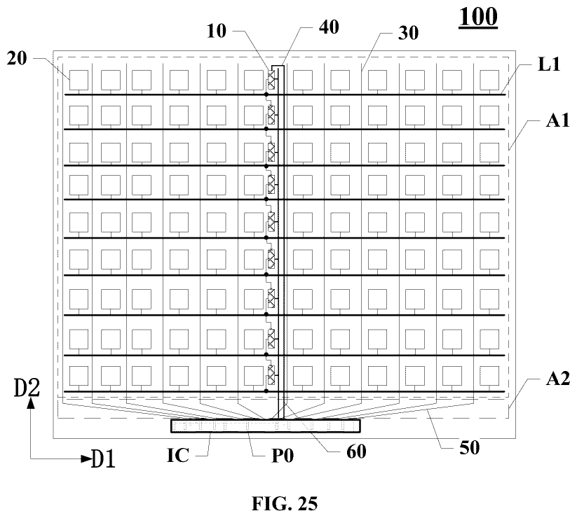

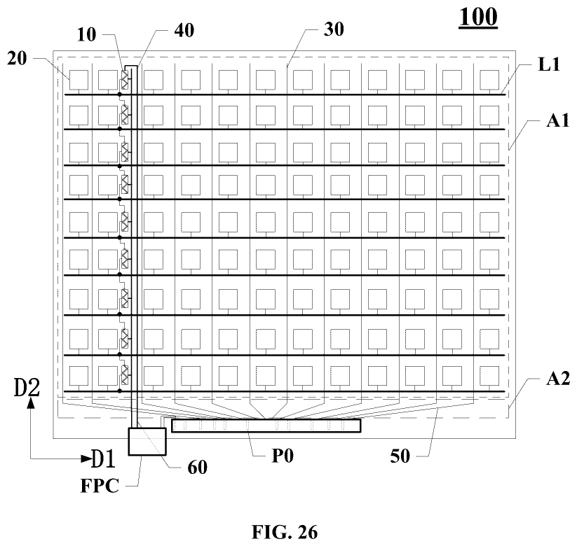

FIG. 25 and FIG. 26 respectively show another planar structure diagram of an exemplary display panel provided by one embodiment of the present disclosure. The embodiments shown in FIGS. 25-26 show a scheme for bonding the connection soldering pad P0 with the control chip IC. The embodiment shown in FIG. 25 shows a scheme for bonding the connection soldering pad P0 with the control chip IC after the second type of connection line 60 is connected to the connection soldering pad P0. The embodiment of FIG. 26 shows a scheme for first electrically connecting the second type of connection line 60 with the flexible circuit board FPC, and then electrically connecting the connection soldering pad P0 through the flexible circuit board FPC lead-out wire, all of which are within the scope of protection claimed by the present disclosure.

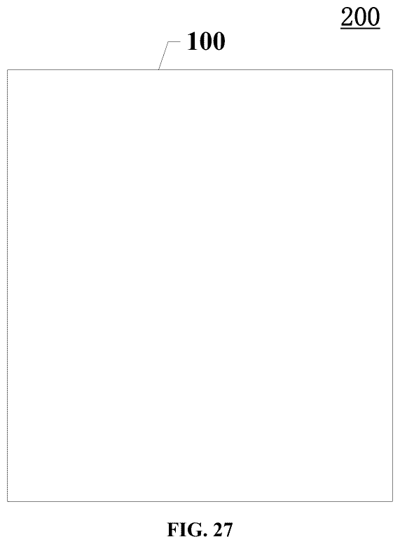

The present disclosure also provides a display device. FIG. 27 shows a structural schematic diagram of an exemplary display device provided by one embodiment of the present disclosure. As shown in FIG. 27, the display device 200 may include the display panel 100 in any of the above embodiments. The display device 200 provided in one embodiment of the present disclosure may be any electronic device with a display function, such as a tablet computer with a display function, a display cabinet display product, a television or a car display device. The display device 200 provided in the embodiment of the present disclosure may have the beneficial effects of the display panel 100 provided in the embodiment of the present disclosure. Details may be referred to the specific description of the display panel 100 in the above embodiments, which will not be repeated in this embodiment.

It can be understood that FIG. 27 only illustrates the display device in a rectangular structure. In some other embodiments of the present disclosure, the display device 200 may also be embodied in a circular, elliptical or any other feasible shape, which is not specifically limited in the present disclosure.

In summary, the display panel and display device provided by the embodiments of the present disclosure have at least the following technical effects.

In the display panel and display device provided by the embodiments of the present disclosure, in the overlapping area of the first type of connection line and the second type of connection line, at least an organic layer may be spaced between the first type of connection line and the second type of connection line. The organic layer may be, for example, a film layer with a relatively large thickness that plays a flattening role in the display panel. When the first type of connection line and the second type of connection line are separated by the organic layer at least in the overlap area, it may be equivalent to increasing the distance between the first type of connection line and the second type of connection line in the overlap area. When the first type of connection line and the second type of connection line in the overlap area are used as two plates of a capacitor, the greater the distance between the two plates, the smaller the coupling capacitance between the two plates will be, which may be conducive to reducing the coupling capacitance generated when the first type of connection line and the second type of connection line overlap, and may be conducive to weakening or eliminating the phenomenon of abnormal display stripes caused by the coupling capacitance, so it may be conducive to improving the overall display effect.

It should be noted that, in this article, relational terms such as “first” and “second” are only used to distinguish one entity or operation from another entity or operation, and do not necessarily require or imply any such actual relationship or order between these entities or operations. Moreover, the terms “include”, “comprises” or any other variations thereof are intended to cover non-exclusive inclusion, so that a process, method, article or device that includes a series of elements includes not only those elements, but also includes other elements not explicitly listed, or also includes elements inherent to such process, method, article or device. In the absence of further restrictions, an element defined by the sentence “includes one . . . ” does not exclude the presence of other identical elements in the process, method, article or device that includes the element.

The above is only a specific implementation of the present disclosure, so that those skilled in the art can understand or implement the present disclosure. Various modifications to these embodiments will be obvious to those skilled in the art, and the general principles defined herein may be implemented in other embodiments without departing from the spirit or scope of the present disclosure. Therefore, the present disclosure will not be limited to the embodiments described herein, but rather is to be consistent with the widest scope consistent with the principles and novel features disclosed herein.

What is claimed is:

1. A display panel, comprising:
a gate driving circuit;
a pixel driving circuit;
a data line; and
a first signal line,
wherein:
the data line is configured to provide a data signal to the pixel driving circuit, and the gate driving circuit is configured to transmit a control signal to the pixel driving circuit;
the first signal line is electrically connected to the gate driving circuit and is configured to transmit a control signal to the gate driving circuit;
the display panel includes a first area and a wiring area, the gate driving circuit and the pixel driving circuit are located in the first area, and the wiring area is located at a side of the first area adjacent to an edge of the display panel;
the wiring area includes a first type of connection line and a second type of connection line, the first type of connection line is electrically connected to the data line, and the second type of connection line is electrically connected to the first signal line;
along a direction perpendicular to a plane where a light-exiting surface of the display panel is located, the first type of connection line and the second type of connection line at least partially overlap to form an overlap area; and
in the overlap area, at least an organic layer is spaced between the first type of connection line and the second type of connection line.

2. The display panel according to claim 1, wherein the second type of connection line comprises:
a main body; and
a connection member connected to the main body,
wherein:
the connection member is located in the overlap area;
along the direction perpendicular to the light-exiting surface of the display panel, the connection member is located on a side of the organic layer facing the light-exiting surface; and
the first type of connection line is located on a side of the organic layer away from the light-exiting surface.

3. The display panel according to claim 2, wherein:
the main body of the second type of connection line is located on the side of the organic layer away from the light-exiting surface of the display panel.

4. The display panel according to claim 3, wherein:
the main body and the first signal line are disposed in a same layer.

5. The display panel according to claim 2, wherein:
the main body of the second type of connection line is located on the side of the organic layer facing the light-exiting surface of the display panel.

6. The display panel according to claim 5, wherein:
the connection member is located at a side of the main body facing the light-exiting surface of the display panel; and/or
the main body of the second type of connection line and the connection member are located in a same layer.

7. The display panel according to claim 1, wherein the second type of connection line comprises:
a main body; and a lead-out member connected to the main body, wherein the lead-out member is located on the side of the organic layer away from the light-exiting surface, and the lead-out member is located on a side of the main body adjacent to the edge of the display panel; or
an opening, wherein, along the direction perpendicular to the plane where the light-exiting surface of the display panel is located, the opening overlaps with the overlap area.

8. The display panel according to claim 1, further comprising:
a shielding member at least located in the overlap area, located between the first type of connection line and the second type of connection line along the direction perpendicular to the plane where the light-exiting surface of the display panel is located, and configured to receive a constant potential signal.

9. The display panel according to claim 8, wherein the second type of connection line comprises:
a main body,
wherein:
along the direction perpendicular to the plane where the light-exiting surface of the display panel is located, the main body overlaps with the first type of connection line; and
the shielding member covers the main body.

10. The display panel according to claim 9, comprising:
a first metal layer, a capacitor metal layer, a second metal layer located on the side of the organic layer away from the light-exiting surface; and
a third metal layer and a fourth metal layer located on the side of the organic layer facing the light-exiting surface,
wherein:
the capacitor metal layer is located between the first metal layer and the second metal layer;
the second metal layer is located on a side of the capacitor metal layer facing the organic layer;
the fourth metal layer is located on a side of the third metal layer away from the organic layer;
the first type of connection line is located in the first metal layer and/or the capacitor metal layer; and
the shielding member is located in the second metal layer and/or the third metal layer.

11. The display panel according to claim 10, wherein the second type connection line further comprises:
a lead-out member connected to the main body,
wherein:
in a same second-type of connection line, the lead-out member is located on a side of the main body adjacent to the edge of the display panel; and
the lead-out member is located in the first metal layer and/or the capacitor metal layer.

12. The display panel according to claim 1, wherein the wiring area also comprises:
a power signal line, wherein the second type of connection line and the power signal line are at least partially arranged in a same layer and are insulated from each other.

13. The display panel according to claim 12, comprising:
a first metal layer, a capacitor metal layer and a second metal layer located on the side of the organic layer away from the light-exiting surface; and
a third metal layer and a fourth metal layer located on the side of the organic layer facing the light-exiting surface,
wherein:
the capacitor metal layer is located between the first metal layer and the second metal layer;
the second metal layer is located on a side of the capacitor metal layer facing the organic layer;
the fourth metal layer is located on a side of the third metal layer away from the organic layer;
the second type of connection line includes a main body overlapping with the first type of connection line along the direction perpendicular to the plane where the light-exiting surface of the display panel is located;
the power signal line is distributed at least in the third metal layer and the fourth metal layer; and
the main body is located in the third metal layer or the fourth metal layer.

14. The display panel according to claim 13, wherein the second type of connection line also comprises:
a lead-out member connected to the main body,
wherein:
in a same second-type of connection line, the lead-out member is located on a side of the main body adjacent to the edge of the display panel; and
the lead-out member is located in the first metal layer or the capacitor metal layer.

15. The display panel according to claim 1, wherein the wiring area comprises:
a connection soldering pad located on a side of the first type of connection line and the second type of connection line adjacent to the edge of the display panel;
wherein:
the connection soldering pad includes a first connection soldering pad and a second connection soldering pad;
the first connection soldering pad is electrically connected to the first type of connection line;
the second connection soldering pad is electrically connected to the second type of connection line;
the wiring area includes a first soldering pad area and a second soldering pad area located at least on one side of the first soldering pad area along a first direction;
the first connection soldering pad is located in the first soldering pad area;
the second connection soldering pad is located in the second soldering pad area; and
the first direction is parallel to an extension direction of the edge of the display panel.

16. The display panel according to claim 15, wherein
the second type of connection line comprises a main body; and a lead-out member connected to the main body, wherein the main body is located on the side of the organic layer facing the light-exiting surface; the lead-out member is located on the side of the organic layer away from the light-exiting surface; and the main body is electrically connected to the second connection soldering pad through the lead-out member, and/or
the gate driving circuit comprises a first group of gate driving circuits, wherein along a second direction, the first group of gate driving circuits do not overlap with the first soldering pad area and the second soldering pad area; and the second direction intersects with the first direction.

17. The display panel according to claim 15, wherein the gate driving circuit comprises:
a first group of gate driving circuits,
wherein:
along a second direction, the first group of gate driving circuits overlaps with the first soldiering pad area; and
the second direction intersects with the first direction.

18. The display panel according to claim 16, wherein:
in the wiring area, the second type of connection line extends along a second direction;
the second direction intersects with the first direction;
the wiring area also includes an auxiliary lead;
one end of the auxiliary lead is electrically connected to the second connection soldering pad; and
another end of the auxiliary lead is electrically connected to an end of the second type of connection line away from the first area.

19. The display panel according to claim 17, wherein:
in the direction perpendicular to the plane where the light-exiting surface of the display panel is located, the auxiliary lead does not overlap with the first type of connection line; or
in the direction perpendicular to the plane where the light-exiting surface of the display panel is located, the auxiliary lead located at a side of the connection soldering pad away from the light-exiting surface of the display panel.

20. A display device, comprising:
a display panel, including:
a gate driving circuit;
a pixel driving circuit;
a data line; and
a first signal line,
wherein:
the data line is configured to provide a data signal to the pixel driving circuit, and the gate driving circuit is configured to transmit a control signal to the pixel driving circuit;
the first signal line is electrically connected to the gate driving circuit and is configured to transmit a control signal to the gate driving circuit;
the display panel includes a first area and a wiring area, the gate driving circuit and the pixel driving circuit are located in the first area, and the wiring area is located at a side of the first area adjacent to an edge of the display panel;
the wiring area includes a first type of connection line and a second type of connection line, the first type of connection line is electrically connected to the data line, and the second type of connection line is electrically connected to the first signal line;
along a direction perpendicular to a plane where a light-exiting surface of the display panel is located, the first type of connection line and the second type of connection line at least partially overlap to form an overlap area; and
in the overlap area, at least an organic layer is spaced between the first type of connection line and the second type of connection line.
